(19) United States
(12) Patent Application Publication
(10) Pub. No.: US 2017/0369994 A1
(43) Pub. Date: Dec. 28, 2017

(54) APPARATUS FOR PROCESSING A WAFER AND METHOD OF DEPOSITING A THIN FILM USING THE SAME

(71) Applicant: WONIK IPS CO., LTD., Pyeongtaek-si Gyeonggi-do (KR)

(72) Inventors: Dae Jun LEE, Pyeongtaek-si Gyeonggi-do (KR); Yong Jin KIM, Osan-si Gyeonggi-do (KR); Choon Kum BAIK, Pyeongtaek-si Gyeonggi-do (KR)

(73) Assignee: WONIK IPS CO., LTD., Pyeongtaek-si Gyeonggi-do (KR)

(21) Appl. No.: 15/624,255

(22) Filed: Jun. 15, 2017

(30) Foreign Application Priority Data
Jun. 28, 2016 (KR) 10-2016-0080809

(51) Int. Cl. C23C 16/44; C23C 16/455; C23C 16/458

(52) U.S. Cl. CPC C23C 16/4408; C23C 16/4586; C23C 16/4412; C23C 16/45544; C23C 16/45565

(57) ABSTRACT

An apparatus for processing a substrate may include a chamber, a substrate support, a showerhead structure and a purge ring structure. The purge ring structure may be arranged at an edge portion of the substrate support to inject a deposition-preventing gas, which may be supplied from the substrate support, to an edge portion of an upper surface of the substrate. The purge ring structure may include a purge ring and a plurality of bosses. The purge ring may be configured to surround the substrate. The bosses may be protruded from an inner surface of the purge ring in a radius direction of the substrate to form a gap between the inner surface of the purge ring and the edge portion of the substrate. The deposition-preventing gas may be supplied to the upper surface of the substrate through the gap.

### CROSS-REFERENCES TO RELATED APPLICATION

The present application claims priority under 35 U.S.C. §119(a) to Korean application number 10-2016-0080809, filed on Jun. 28, 2016, in the Korean Intellectual Property Office, which is incorporated herein by reference in its entirety.

### BACKGROUND

### 1. Technical Field

Various embodiments generally relate to an apparatus for processing a wafer and a method of depositing a thin film using the same, more particularly to an atomic layer deposition apparatus and a method of deposition a thin film using the apparatus.

### 2. Related Art

Generally, in order to deposit a thin film on a wafer or a glass substrate, a physical vapor deposition (PVD) apparatus, a chemical vapor deposition (CVD) apparatus, etc., may be used.

The CVD apparatus may include a substrate support, an edge ring and a purge ring. The edge ring and the purge ring may be arranged at an edge portion of the substrate support. The edge ring and the purge ring may include a purge gas nozzle configured to prevent a layer from being deposited on edge portions of an upper surface and a bottom surface of the wafer. The edge ring may be configured to inject a purge gas to the edge portion of the upper surface of the wafer. The purge ring may be configured to inject the purge gas to the edge portion of the bottom surface of the wafer.

Recently, as a semiconductor device may be highly integrated, a design rule may become remarkably reduced so that a minute pattern the thin film may be required. In order to meet the requirement, an atomic layer deposition (ALD) apparatus may be used. Further, in order to improve a yield of the semiconductor device, the edge portion of the wafer may be used for a device region.

However, because the edge ring may be configured to inject the purge gas to the edge portion of the upper surface of the wafer, improving the yield of the semiconductor device may be limited due to the edge ring.

### SUMMARY

In an embodiment, an apparatus for processing a substrate may include a chamber, a substrate support, a showerhead structure and a purge ring structure. The chamber may have a sealed process region. The substrate support may be arranged at a lower region in the chamber to support the substrate. The substrate support may include a gas passageway through which a deposition-preventing gas may be exhausted. The deposition-preventing gas may be supplied to a sidewall of the substrate support by the gas passageway. The showerhead structure may be arranged at an upper region in the chamber to supply a source gas and a reaction gas to the substrate support. The purge ring structure may be arranged at an edge portion of the substrate support to inject the deposition-preventing gas, which may be supplied from an inner portion of the substrate support, to an edge portion of an upper surface of the substrate. The purge ring structure may include a purge ring and a plurality of bosses. The purge ring may be configured to surround the substrate. The bosses may be protruded from an inner surface of the purge ring in a radius direction of the substrate to form a gap between the inner surface of the purge ring and the edge portion of the substrate. The deposition-preventing gas may be supplied to the upper surface of the substrate through the gap.

For example, each of the bosses has a thickness of about 0.1 mm to about 1.5 mm toward a center point of the purge ring. Further, the bosses are at least three for providing the gap between the edge portion of the substrate and the inner surface of the purge ring. Thus, the edge portion of the substrate is not contacted with the inner surface of the purge ring by the gap.

In an embodiment, in a method of depositing a thin film, a substrate may be placed on a substrate support in a chamber. The substrate support may be upwardly moved to a process region in the chamber. The thin film may be deposited on the substrate in the process region. The substrate support may be downwardly moved. The substrate may be unloaded from the chamber. Depositing the thin film may include supplying a source gas to the substrate, supplying a reaction gas to the substrate, and injecting a deposition-preventing gas to an edge portion of an upper surface of the substrate during supplying the reaction gas.

### BRIEF DESCRIPTION OF THE DRAWINGS

FIG. 1 is a cross-sectional view illustrating an apparatus for processing a substrate in accordance with example embodiments;

FIG. 2 is an enlarged cross-sectional view illustrating a purge ring structure in accordance with example embodiments;

FIG. 3 is a perspective view illustrating a purge ring structure in accordance with example embodiments;

FIG. 4 is a plan view illustrating a purge ring structure in accordance with example embodiments;

FIG. 5 is a timing chart illustrating a method of depositing a thin film by an ALD process in accordance with example embodiments; and

FIG. 6 is a timing chart illustrating a method of depositing a thin film by a CVD process in accordance with example embodiments.

### DETAILED DESCRIPTION

Hereinafter, example embodiments will be described below with reference to the accompanying drawings through various examples of embodiments.

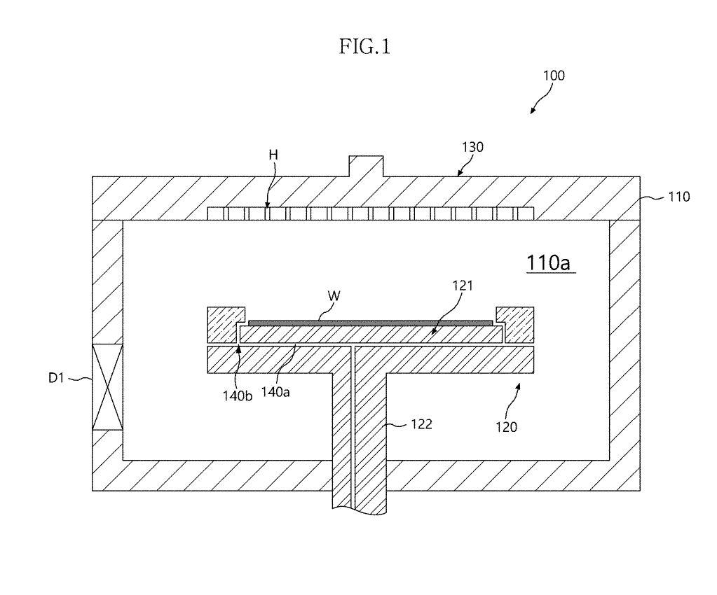

FIG. 1 is a cross-sectional view illustrating an apparatus for processing a substrate in accordance with example embodiments.

Referring to FIG. 1, an apparatus 100 for processing a substrate W may include an ALD apparatus. The ALD apparatus 100 may include a vacuum chamber 110 configured to define a process region 110a. A substrate support 120 may be arranged in the vacuum chamber 110.

A showerhead structure 130 may be installed at a top surface of the process region 110a. The showerhead structure 130 may be configured to supply a process gas including a source gas and a reaction gas into the process region 110a. The showerhead structure 130 may include a plurality of injecting holes configured to inject the process gas to the substrate W.

The substrate support 120 may include a stage 121 and a hollow support 122. The stage 121 may be configured to receive the substrate W. The hollow support 122 may be installed on a bottom surface of the process region 110a to support the stage 121.

A main gas passageway 140a may be formed in the substrate support 120. The main gas passageway 140a may be connected with a deposition-preventing gas source. Thus, a deposition-preventing gas may be supplied through the main gas passageway 140a.

A purge ring structure 150 may be arranged at an edge portion of an upper surface of the substrate support 120 to define a sub-gas passageway 140b. The sub-gas passageway 140b may be connected to the main gas passageway 140a to supply the deposition-preventing gas supplied from the sub-gas passageway 140b to a bottom surface of the substrate W and a sidewall of the substrate support 120. Particularly, in order to provide the edge portion of the bottom surface of the substrate W with the deposition-preventing gas, the purge ring structure 150 may be positioned at the edge portion of the substrate support 120.

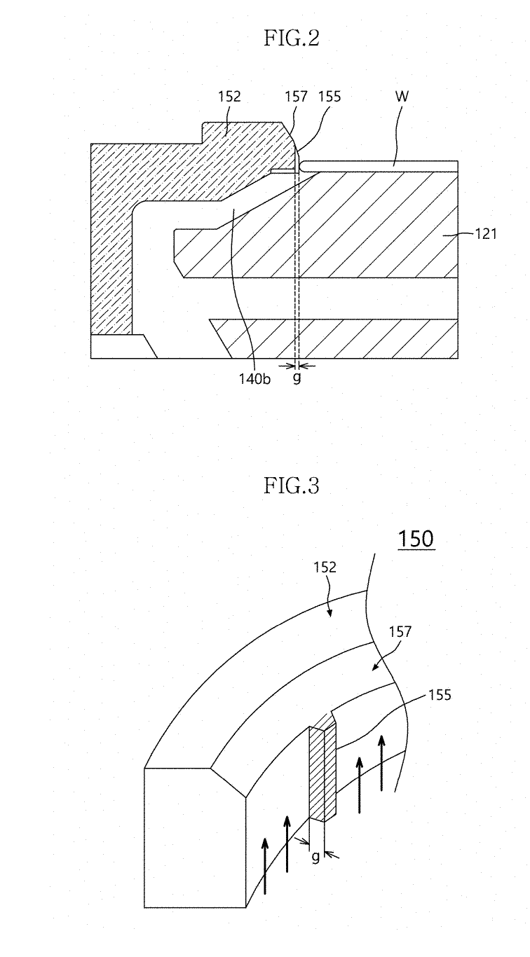

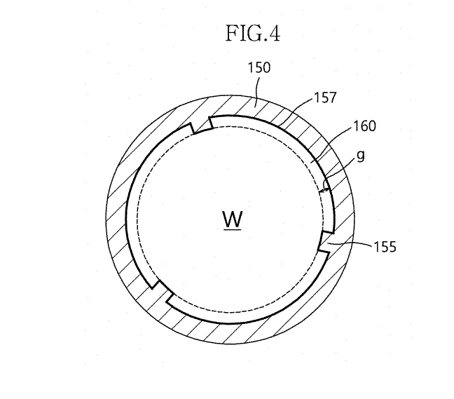

FIG. 2 is an enlarged cross-sectional view illustrating a purge ring structure in accordance with example embodiments, FIG. is a perspective view illustrating a purge ring structure in accordance with example embodiments, and FIG. 4 is a plan view illustrating a purge ring structure in accordance with example embodiments.

Referring to FIGS. 2 to 4, the purge ring structure 150 may include an annular purge ring 152 and a plurality of bosses 155. The bosses 155 may be formed on an inner surface of the purge ring 152. In example embodiments, the bosses 155 may be three.

The purge ring 152 may be installed at an edge portion of the stage 121 of the substrate support 120 to surround the substrate W.

The bosses 155 may be protruded from the inner surface of the purge ring 152 in a radius direction of the substrate W. The bosses 155 may function as to adjust a gap between the substrate W and the purge ring 152. Thus, the bosses 155 may form a gap 160 between the inner surface of the purge ring 152 and the edge portion of the substrate W. Therefore, the deposition-preventing gas and an additional reaction gas may be uniformly supplied to the upper surface of the substrate W through the gap 160. In order to uniformly distribute the gas on the edge portion of the substrate W, the bosses 155 may be spaced apart from each other by a substantially same interval. Each of the bosses 155 may have a thickness of about 0.1 mm to about 1.5 mm toward a center point of the purge ring 152. The inner surface of the purge ring 152 may not make contact with the edge portion of the substrate W due to the bosses 155 to define the gap 160.

An inclined portion 157 may be formed between an upper surface of the purge ring 152 and an upper surface of the boss 155. Particularly, the inclined portion 157 may be formed at an upper portion of the inner surface of the purge ring 152. The inclined portion 157 may function as to align the substrate W with the substrate support 120.

According to example embodiments, the purge ring structure 150 may function as to uniformly inject the deposition-preventing gas and the additional reaction gas on the edge portions of the upper surface and the bottom surface of the substrate W so that a deposited thickness of a thin film, for example, a metal layer may be accurately controlled. The gaps 160 may have uniform size considered as the thickness uniformity of the thin film.

The apparatus for processing the substrate may include the purge ring structure configured to supply the deposition-preventing gas and the additional reaction gas through the gap between the purge ring and the substrate with supplying of the gas to the bottom surface of the substrate without an edge ring. Therefore, the edge portion of the substrate may not be covered with a structure. Further, the gases may be effectively supplied to the upper surface and the bottom surface of the substrate so that the edge portion of the substrate may be used for a device region. Furthermore, the thin film deposited on the substrate may have uniform thickness. As a result, a yield of the semiconductor device may be remarkably improved.

The apparatus for processing the substrate may be operated as follows.

The substrate W may be loaded into the chamber 110 through an entrance D1. The substrate W may be placed on the stage 121 of the substrate support 120. In example embodiments, because the apparatus may include the purge ring 150 installed at the substrate support 120 without the edge ring, the substrate support 120 with the substrate W may be upwardly moved to the process region.

The showerhead structure 130 may inject the source gas, the reaction gas and the purge gas. The purge ring structure 150 may inject the deposition-preventing gas and the additional reaction gas to form the thin film having the uniform thickness on the substrate.

After forming the thin film, the substrate support 120 may be downwardly moved. The substrate may be unloaded from the chamber 110 through an exit D2.

FIG. 5 is a timing chart illustrating a method of depositing a thin film by an ALD process in accordance with example embodiments.

Referring to FIG. 5, a method of forming the thin film by the ALD process may include introducing the source gas, supplying the purge gas, introducing the reaction gas and supplying the purge gas. The source gas and the reaction gas may be changed in accordance with materials of the thin film. During depositing the thin film, in order to suppress the thin film from being deposited on the bottom surface of the substrate W, the deposition-preventing gas may be continuously supplied through the sub-gas passageway 140b. The deposition-preventing gas may include an inert gas such as an Ar gas, a He gas, a Ne gas, a Kr gas, a Xe gas, an Rn gas, etc. Further, the additional reaction gas such as a H₂ gas may be supplied simultaneously with the reaction gas. As a result, reactions of the thin film deposited on the edge portion of the substrate W may be controlled.

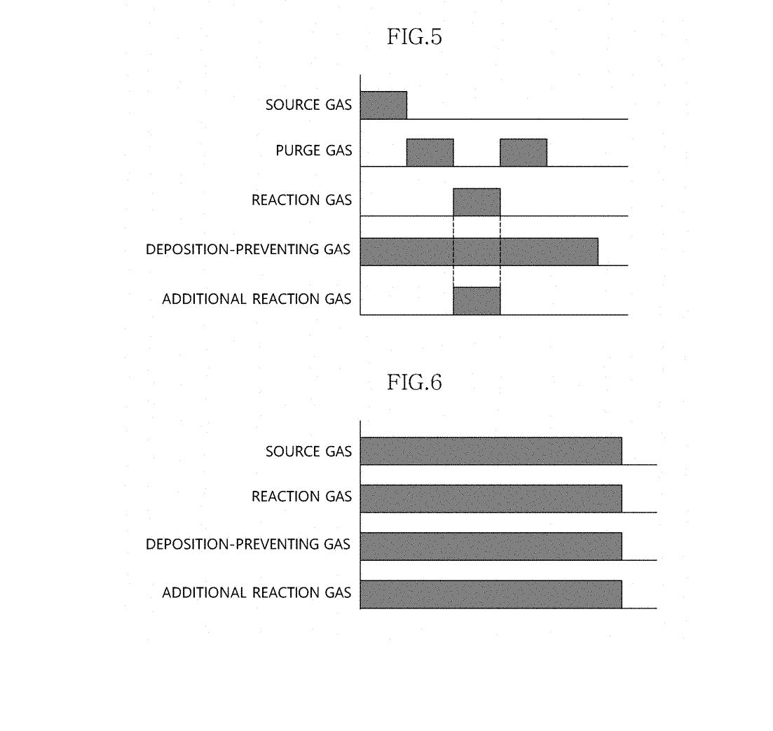

FIG. 6 is a timing chart illustrating a method of depositing a thin film by a CVD process in accordance with example embodiments.

Referring to FIG. 6, when the purge ring structure 150 may be installed at a CVD apparatus, the source gas, the reaction gas, the deposition-preventing gas and the additional reaction gas may be simultaneously supplied to the CVD apparatus.

In example embodiments, the reaction gas and the additional reaction gas may include substantially the same material.

According to example embodiments, the apparatus for processing the substrate may include the purge ring structure with the bosses on the inner surface of the purge ring, which may be configured to surround the substrate support, without the edge ring. Therefore, the deposition-preventing gas may be supplied to the edge portion of the bottom surface of the substrate. The bosses may form the gap between the purge ring and the edge portion of the substrate. The gap may function as to selectively supply the deposition-preventing gas and the additional reaction gas to the upper surface of the substrate. As a result, the deposition uniformity of the thin film on the substrate may be improved.

The above embodiments of the present disclosure are illustrative and not limitative. Various alternatives and equivalents are possible. The examples of the embodiments are not limited by the embodiments described herein. Nor is the present disclosure limited to any specific type of semiconductor device. Other additions, subtractions, or modifications are obvious in view of the present disclosure and are intended to fall within the scope of the appended claims.

What is claimed is:

1. An apparatus for processing a substrate, the apparatus comprising:
a chamber having a sealed process region;
a substrate support arranged at a lower region of the chamber to receive the substrate, the substrate support including a gas passageway configured to exhaust a deposition-preventing gas;
a showerhead arranged at an upper region of the chamber to supply a source gas and a reaction gas to the substrate support; and
a purge ring structure arranged at an edge portion of the substrate support to supply the deposition-preventing gas supplied from the substrate support to an edge portion of an upper surface of the substrate,
wherein the purge ring structure comprises a purge ring installed at an edge portion of the substrate support to surround the substrate, and a plurality of bosses protruded from an inner surface of the purge ring in a radius direction of the substrate, and the bosses have function as to form a gap between the inner surface of the purge ring and the edge portion of the substrate through which the deposition-preventing gas is supplied to the upper surface of the substrate.

2. The apparatus of claim 1, wherein each of the bosses has a thickness of about 0.1 mm to about 1.5 mm toward a center point of the purge ring.

3. The apparatus of claim 2, wherein the bosses are at least three for providing the gap between the edge portion of the substrate and the inner surface of the purge ring.

4. The apparatus of claim 1, wherein the purge ring structure further comprises an inclined portion formed at upper portion of an inner surface of the purge ring to align the substrate with the substrate support.

5. The apparatus of claim 1, wherein the deposition-prevention gas comprises an Ar gas.

6. A method of deposition a thin film using the apparatus in claim 1, the method comprising:
loading the substrate on the substrate support;
upwardly moving the substrate support to the process region;
depositing the thin film on the substrate;
downwardly moving the substrate support; and
unloading the substrate from the chamber,
wherein depositing the thin film comprises:
supplying a source gas to the substrate;
supplying a reaction gas to the substrate; and
supplying the deposition-preventing gas to the edge portion of the upper surface of the substrate through the gap during supplying the source gas and the reaction gas.

7. The method of claim 6, further comprising supplying an additional reaction gas to the edge portion of the substrate through the gap.

8. The method of claim 7, wherein the additional reaction gas comprises a material substantially the same as that of the reaction gas.

9. The method of claim 6, wherein the deposition-preventing gas comprises an Ar gas.
